(19) United States
(12) Patent Application Publication
(10) Pub. No.: US 2006/0137608 A1
(43) Pub. Date: Jun. 29, 2006

(54) Atomic layer deposition apparatus

(76) Inventors: Seung Woo Choi, Daejeon (KR); Chun Soo Lee, Daejeon (KR); Kwang Lae Park, Daejeon (KR)

Correspondence Address: KNOBBE MARTENS OLSON & BEAR LLP, 2040 MAIN STREET, FOURTEENTH FLOOR, IRVINE, CA, 92614, US

(21) Appl. No.: 11/318,786

(22) Filed: Dec. 27, 2005

(30) Foreign Application Priority Data
Dec. 28, 2004 (KR) 10-2004-0113898

(51) Int. Cl. C23C 16/00

(52) U.S. Cl. 118/715

(57) ABSTRACT

An atomic layer deposition (ALD) apparatus is, suitable for thermal ALD and plasma-enhanced ALD of conductive and non-conductive films. The ALD apparatus can maintain electrical insulation of a gas dispersion structure, such as a showerhead assembly, which acts as an RF electrode to generate plasma inside a reaction chamber while depositing electrically conductive films in the reaction chamber. Fine tubules of micro-feeding tube assembly prevents plasma generation in them and reactive gases each have separate flow paths through the micro-feeding tube assembly. Process gases out of the micro-feeding tube assembly enter narrow grooves of a helical flow inducing plate and form helical flows which mix well each other. Symmetrically mounted pads on showerhead assembly and flow guiding plate maintain a symmetrical gap through which an inert gas flows continuously to keep reactive gases outside the gap and unwanted film deposition in the gap. Longer operating time before maintenance (cleaning) and thus higher productivity can be achieved.

### REFERENCE TO RELATED APPLICATIONS

This application claims the priority benefit under 35 U.S.C. §119(a) of Korean Application No. 10-2004-0113898, filed Dec. 28, 2004. This application is also related to U.S. utility application Ser. No. 10/486,311, filed Feb. 6, 2004, attorney docket no. ASMGEN.001APC.

### FIELD OF THE INVENTION

The present invention relates to an atomic layer deposition apparatus capable of depositing a uniform thin film. In particular, the present invention relates to the reaction chamber structure of a plasma enhanced atomic layer deposition apparatus which is designed to prevent electrical short between plasma generating electrode and electrically grounded other parts, despite use of conductive elements during deposition.

### BACKGROUND AND SUMMARY OF THE INVENTION

As semiconductor integration technologies advance, methods for depositing ultra thin films in a uniform and conformal manner, such as in a via or trench pattern, become increasingly important. Currently, the most advanced process for ensuring such a nano-scale thickness ultra thin film in semiconductor device fabrication is known as atomic layer deposition (ALD), a variant of conventional CVD processes.

Unlike a conventional CVD method, where all process gases are simultaneously supplied (in flow) or removed (outflow), in an ALD method each atomic layer of thin film is formed by alternate and sequential supply of process gases, which are separated in space and in time. Thus mutually reactive reactant gases do not meet each other in the gas phase. Rather, typically one reactant pulse adsorbs in a self-limiting manner, excess reactant is removed from the reaction space, and a subsequent reactant pulse reacts with the adsorbed reactant. Frequently inert gases are supplied to purge the inside of the ALD apparatus between reactant pulses in order to prevent their mixing in the gas phase. These inert gases are called purge gases. Some ALD recipes involve three or more different reactant pulses in one cycle, with purge or other removal steps between pulses.

When the aforementioned ALD method is used, material is adsorbed on the surface of the substrate. A thin film is formed uniformly over the entire surface of a substrate regardless of the quantity of the process gas in each cycle because the amount of adsorbed molecules on the surface of a substrate is limited up to a maximum of a monolayer. Therefore, a uniform thickness of thin film can be formed even in the areas of high aspect ratio or large step difference, even when the thin film is formed with a thickness of several nanometers. Furthermore, the thickness of the thin film can be easily controlled by the number of process gas supply cycles, or ALD cycles, due to the self-saturating nature of the adsorption and the reactions.

Adding to the aforementioned advantages of ALD, we can get more useful benefits when a plasma is generated during the ALD cycles. For example, the use of plasma can help to broaden the choice of source chemicals. Plasma as an additional energy source to thermal energy can activate the reaction between the chemicals which are not otherwise reactive. For example, tantalum halides (e.g. TaCl₅, TaF₅) do not react readily with H₂ at low temperatures (400° C. or lower). This implies that one cannot use tantalum halides and H₂ for ALD of Ta by the conventional thermal ALD at a temperature less than 400° C., making the process unsuitable for many back end of line (BEOL) metallization processes. However, atomic hydrogen or hydrogen ions from hydrogen plasma can react very effectively with tantalum halides to form Ta metal film at low temperatures. H₂ gas plasma contains the neutral hydrogen radicals and/or the hydrogen ions and can be generated, e.g., by applying a radio frequency (RF) power to H₂ gas or a mixture of H₂ gas and an inert gas. Pure Ta metal film can thus be deposited by using plasma enhanced atomic layer deposition (PEALD).

Therefore, in the PEALD technique, a thin film can be deposited by using chemical species which do not react readily with each other using only thermal energy. PEALD of TaN is described in detail as an example. Ta source TaF₅ is vaporized and supplied to the reaction chamber to be adsorbed on a substrate. After the adsorption is completed, an inert gas flows into the reaction chamber and on the substrate to purge excess gaseous or weakly adsorbed TaF₅ and vent them from the reaction chamber. Subsequently, H₂ gas is supplied to the substrate where TaF₅ is adsorbed, and H₂ gas plasma is generated. Hydrogen atoms or hydrogen ions generated in the plasma react with TaF₅ (or adsorbed fragments of TaF₅) on the substrate to form the tantalum metal and a reaction by-product HCl, which is volatile and removed from the substrate in a gaseous state. When the reaction of the substrate is completed, the plasma is turned off, and the remaining HCl is removed. At this time, an inert purge gas may be optionally supplied in order to facilitate the removal of the HCl. By repeating this ALD cycle, a Ta metal thin film can be deposited up to a desired thickness. On the other hand, in the above example, instead of using a separate inert gas, H₂ gas flow can continue after the plasma power is shut off and may be used as a purge gas. In this case, Ta source gas pulses and plasma power pulses alternate while H₂ gas flows continuously.

In addition, the area of reaction between sequentially supplied chemical can be confined only to the area where plasma-activated species reach (usually on the substrate) so that extraneous film deposition at other parts of reaction chamber can be suppressed where plasma is not generated.

In addition to the advantages aforementioned, PEALD usually can produce the film which has higher density and less impurity than conventional thermal ALD. Because of these reasons, PEALD has received attention from the semiconductor industry (see for example, Sherman, U.S. Pat. No. 6,342,277).

Lee et al.'s Korean Patent No. 273473 and U.S. Pat. No. 6,645,574, disclose an ALD method in which plasma is generated periodically during the ALD cycles to activate one of the reactants.

Lee et al. further describes an example of a PEALD chamber in Korean Patent Application 2001-46802 filed on Aug. 2, 2001 and U.S. patent application Ser. No. 10/486,311 filed on Feb. 6, 2004, expressly incorporated herein by reference.

This type of apparatus disclosed by Lee et al. and reproduced here as in FIG. 1 is designed for and well suited for PEALD. However, there is a limitation that it cannot be used for multi-layer film deposition or graded film deposition, which includes both PEALD and thermal ALD of a metallic film. Once thermal ALD of metallic film is performed in the reaction chamber, PEALD is not possible in the reaction chamber before removing the metallic film due to shorting of the plasma-generating electrodes. Any metallic film deposition due to thermal activation without plasma, whether during thermal ALD or PEALD, can coat insulator parts and electrically short the electrodes. Thus apparatus service time between reaction chamber cleanings may be shortened.

FIG. 2 illustrates the structure of the gas inlet parts of U.S. application Ser. No. 10/486,311. The disclosed micro-feeding tube assembly 14, made of non-conducting material, is disposed on the insulation wall 24 in order to prevent the plasma generation above the showerhead. Without the micro-feeding tube construction, such plasma generation might occur due to electrical potential difference between the showerhead assembly (26, 28), which is connected to the RF terminal (not shown), and the gas inlet tube 10, which is electrically grounded. Although such a structural design can suppress the plasma generation above the showerhead, some risk remains for film deposition 16 on the surface of micro-feeding tube assembly 14 due to the thermal reaction. It is because all the process gases share the same inlet tube and the parts are heated by conduction, which may allow thermal reaction on the micro-feeding tube assembly 14. If the deposited films 16 are electrically conductive, the electrical insulation between the showerhead assembly (26, 28) and the gas inlet tube 10 will be no longer effective and thus the plasma density will be reduced or the plasma will not be generated at all where it is desired over the substrate, thus causing detrimental effects on film deposition such as lower deposition rate, poorer uniformity, or no deposition at all. So it is desirable to prevent film deposition on the micro-feeding tube assembly 14.

Another potential problem with the structure of U.S. application Ser. No. 10/486,311 is the build-up of film deposition at the insulation wall as shown in FIG. 3. Since the insulation wall 24 abuts the showerhead assembly (26, 28) tightly and the wall fringe 25 is very close to the reaction region 27, a metal film 23 may be deposited after numerous process runs on the bottom of insulation wall 24 and also maybe on the bottom of the plasma generation barrier wall 22, which is electrically grounded. If the metal film 23 continues to grow on the showerhead insulation wall 24 and/or the plasma generation barrier wall 22, it may cause an electrical short between the showerhead assembly (26, 28) and the plasma generation barrier wall 22 to hinder the plasma generation in the reaction region 27. Even a slight deposition of metallic film on the wall fringe 25 may disturb the local electrical field. This may cause non-uniform and/or asymmetric plasma, particularly at the substrate edge, and thus non-uniform deposition of the film on the substrates 32.

In addition, another problem with the structure of U.S. application Ser. No. 10/486,311 is that a circular gap 544 (see FIG. 1) through which purge gas flows is difficult to control due to assembly variation. For example, where the reaction chamber is designed so as to maintain the circular gap 544 in a width of 2 mm, variation during assembly may be as large as 0.5 mm, and then the narrowest and the widest sides of the circular gap 544 become 1.5 mm and 2.5 mm, respectively. Such an asymmetric circular gap makes the purge gas flow through it asymmetrically. Accordingly, the flow of gas at the edge of the substrate becomes asymmetric, and causes non-uniformity of film deposition on the substrate, in particular at the substrate edge.

In order to continue to deposit conductive film on the substrate using either PEALD or conventional thermal ALD, it is desirable to maintain electrical insulation despite deposition of metallic film due to thermal reaction between reactants.

For an example of Ru ALD, an ALD film growth rate during a thermal ALD cycle is higher than of PEALD. However, the ALD process may have a long incubation time before film growth, whereas the PEALD process has a short incubation time. In this case, the ALD apparatus according to the present invention can be employed. Namely, the PEALD process is firstly performed to form a thin Ru film with a short incubation time, and then, the ALD process having a higher film growth rate is performed, so that it is possible to deposit maximum thickness of Ru film in a short time.

The preferred embodiments of the present invention provide an apparatus capable of PEALD, thermal ALD, and a combined process of PEALD and thermal ALD for metallic or other conductive film deposition. The embodiments also provide multi-layer or graded film deposition by any combination of PEALD and/or thermal ALD of dielectric films and/or metallic films.

The preferred embodiments also provide a deposition apparatus capable of maintaining an electrical insulation in a reaction chamber and continuously generating plasma by preventing unnecessary film deposition within the reaction chamber when a conductive thin film is deposited by using PEALD and/or ALD processes.

The preferred embodiments of the present invention also provide a deposition apparatus capable of continuously forming a thin film by employing a combination of PEALD and ALD processes or a series thereof.

The preferred embodiments of the present invention also provide a deposition apparatus capable of depositing a thin film by using a PEALD or ALD process by separately supplying a plurality of process gases to a reaction chamber and mixing the process gases in the reaction chamber.

According to an aspect of the present invention, there is provided an ALD apparatus for depositing a thin film on a substrate, comprising a substrate support for supporting the substrate, a reaction chamber wall defining a reaction chamber, a gas inflow tube connected to a source of process gas and communicating with the reaction chamber, a showerhead assembly which defines a reaction space together with the substrate support and includes a plurality of holes connected to the gas inflow tube to supply gas to the reaction space, a showerhead insulating plate made of an insulating material and disposed on the showerhead assembly, a gas flow guiding plate disposed on the showerhead insulating plate, a gas outlet for venting gas from the reaction chamber, and a RF connection port connected to the showerhead assembly to supply RF power, wherein purge gas passages are defined between the showerhead assembly and the showerhead insulating plate, between the showerhead insulating plate and the gas flow guiding plate, and between the gas flow guiding plate and the reaction chamber wall.

In the above aspect of the present invention, the ALD apparatus may further comprise a plurality of pads symmetrically mounted between the showerhead assembly and the showerhead insulating plate, the height of which determines a gap between the showerhead assembly and showerhead assembly insulating plate.

In addition, the pads may be machined directly on the showerhead insulating plate or the showerhead assembly.

In addition, the ALD apparatus may further comprise a plurality of pads symmetrically mounted between the gas flow guiding plate and the reaction chamber wall, the height of which determines a gap between the gas flow guiding plate and the reaction chamber wall.

In addition, the pads may be machined directly on the gas flow guiding plate or the reaction chamber wall.

In addition, the ALD apparatus may further comprise a flanged cylinder type gas manifold having gas inlets and outlets.

In addition, the RF connection port may pass through the reaction chamber wall to be connected to the showerhead assembly and electrically insulated from the reaction chamber wall.

In addition, the ALD apparatus may further comprise a heating plate disposed under the substrate support to heat the substrate.

In addition, the ALD apparatus may further comprise a heater provided on the reaction chamber wall.

In addition, the substrate support may be a pedestal that can be lifted up to contact the reaction chamber wall to define the reaction chamber, and the pedestal may be dropped to be separated from the reaction chamber wall, so that the substrate can be mounted or detached.

According to another aspect of the present invention, there is provided an ALD apparatus for depositing a thin film on a substrate, comprising a substrate support for supporting the substrate, a reaction chamber wall mounted above the substrate support and defining a reaction chamber, a gas inflow tube having a plurality of gas inlets configured to allow a plurality of reactive gases to separately communicate with into the reaction chamber, a gas dispersion structure which defines a reaction space together with the substrate support and supplies the process gases to the reaction space, a micro-feeding tube assembly disposed between the gas inflow tube and the gas dispersion structure and having a plurality of fine tubules, and a helical flow inducing plate disposed between the micro-feeding tube assembly and the gas dispersion structure.

In the above aspect of the present invention, the micro-feeding tube assembly may comprise an electrically conductive micro-feeding tube sub-assembly connected to the gas inflow tube, and an insulating micro-feeding tube sub-assembly connected to the helical flow inducing plate.

In addition, inner diameters of the fine tubules of the electrically conductive micro-feeding tube sub-assembly and the insulating micro-feeding tube sub-assembly may be in a range from 0.1 mm to 1.2 mm.

In addition, fine tubules of the electrically conductive micro-feeding tube sub-assembly and fine tubules of the insulating micro-feeding tube sub-assembly may be of the same size and at the same position and aligned with each other to form a plurality of single conduits.

In addition, the ALD apparatus may further comprise an insulating plate made of an insulating material and disposed on the gas dispersion structure, a gas flow guiding plate disposed on the insulating plate, a gas outlet for venting the gas out of the reaction chamber, and a RF connection port connected to the gas dispersion structure to supply a RF power, wherein purge gas passages are defined between the gas dispersion structure and the insulating plate, between the insulating plate and the gas flow guiding plate, and between the gas flow guiding plate and the reaction chamber wall.

In addition, the ALD apparatus may further comprise a plurality of pads symmetrically formed between the gas dispersion structure and the insulating plate, wherein a width of the gas passage between the gas dispersion structure and the insulating plate is determined by heights of the pads.

In addition, the pads may be machined directly on the insulating plate or the gas dispersion structure.

In addition, the ALD apparatus may further comprise a plurality of pads symmetrically formed between the gas flow guiding plate and the reaction chamber wall, wherein a width of the purge gas passage between the gas flow guiding plate and the reaction chamber wall is determined by height of the pads.

In addition, the pads may be machined directly on the gas flow guiding plate or the reaction chamber wall.

In addition, the helical flow inducing plate may be electrically and mechanically connected to the gas dispersion structure to have an electrical potential equal to that of the gas dispersion structure.

In addition, a plurality of fine holes facing a plurality of the fine tubules of the insulating micro-feeding tube sub-assembly may be formed on the upper side of the helical flow inducing plate, and wherein a plurality of grooves are formed on the lower side of the helical flow inducing plate, which deflects the direction of gas flows out of the fine holes into a mixing region formed at the center of the helical flow inducing plate.

In addition, the grooves may be skewed clockwisely or counter-clockwisely, wherein the mixing region has a shape of disc, and wherein the inducing grooves are connected to the mixing region so as to contact a circumference of the mixing region.

In addition, the gas dispersion structure may comprise a volume adjusting horn. The volume adjusting horn has a shape of funnel, the diameter of which increases from an upper portion to a lower portion thereof. The shape of the volume adjusting horn allows the process gas to distribute uniformly, evenly and smoothly over the substrate and, at the same time, minimizes the volume of the inner part of the gas dispersion structure.

In addition, the gas dispersion structure may be a showerhead assembly, further including a gas dispersion perforated grid downstream of the volume adjusting horn.

In addition, the helical flow inducing plate may be fixed at an upper opening of the volume adjusting horn, wherein the helical flow inducing plate is electrically and mechanically connected to the showerhead assembly to have an electrical potential equal to that of the showerhead assembly.

In addition, the ALD apparatus may further comprise a flanged cylinder type gas manifold having gas inlets and outlets.

In addition, the RF connection port may pass through the reaction chamber wall to be connected to the showerhead assembly and electrically insulated from the reaction chamber wall.

In addition, the gas inflow tube and the micro-feeding tube assembly may be configured to introduce gases substantially perpendicular to the helical flow inducing plate.

In addition, the helical flow inducing plate may include a plurality of grooves extending in a plane substantially parallel to the substrate support, where the grooves are configured to direct gases in a spiral prior to entering the gas dispersion structure in a direction substantially perpendicular to the substrate support

### BRIEF DESCRIPTION OF THE DRAWINGS

The above and other features and advantages of the present invention will become more apparent by describing in detail exemplary embodiments thereof with reference to the attached drawings, which are meant to illustrate and not to limit the invention, and in which:

FIG. 1 is a cross sectional view showing a prior-art ALD apparatus;

FIG. 2 is a cross sectional view showing a gas inflow portion of the prior-ALD apparatus of FIG. 1;

FIG. 3 is a detailed cross sectional view showing a portion of the prior-art ALD apparatus of FIG. 1;

FIG. 4 is a schematic cross sectional view showing an ALD apparatus according to an embodiment of the present invention;

FIG. 5 is an enlarged cross sectional view showing a process gas inflow unit of the ALD apparatus of FIG. 4;

FIG. 6 is a schematic perspective view showing upper and lower portions of a helical flow inducing plate of the process gas inflow unit of FIG. 5;

FIG. 7 is a schematic isometric view showing a gas flow in the process gas inflow unit, the micro-feeding tube assembly and the helical flow inducing plate of the ALD apparatus according to an embodiment of the present invention;

FIG. 8 is a schematic partially cut-away, isometric view showing an inert gas flow in the ALD apparatus according to the embodiment of FIG. 4; and

FIG. 9 is a schematic, enlarged, cut-away, perspective view showing an inert gas flow for preventing unwanted deposition and particle generation in the ALD apparatus according to the embodiment of FIG. 4.

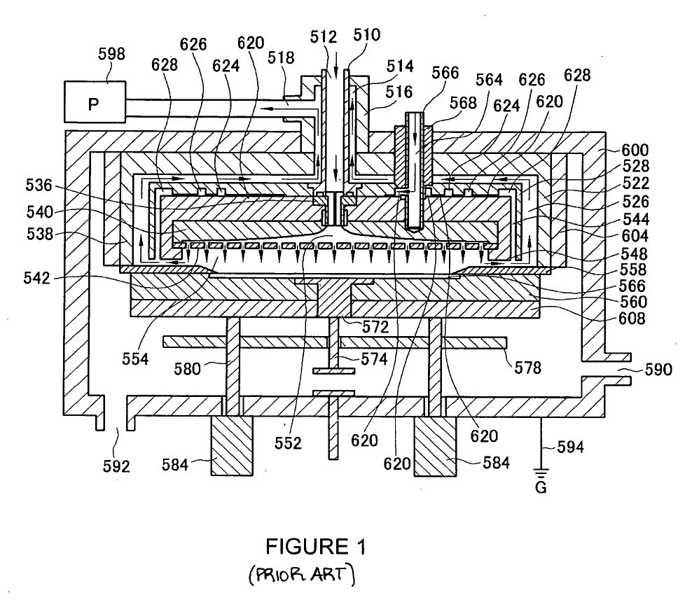

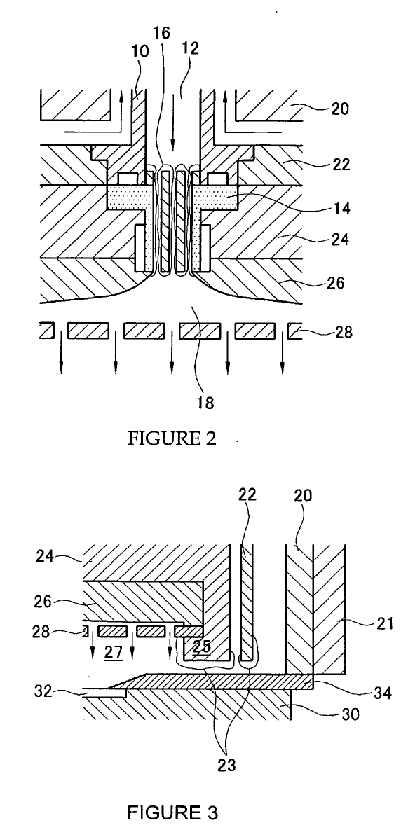

### DETAILED DESCRIPTION OF THE PREFERRED EMBODIMENTS

Hereinafter, exemplary embodiments of the present invention will be described in detail with reference to the attached drawings such that the present invention can be easily put into practice by those skilled in the art. The present invention can be embodied in various forms, but is not limited to the embodiments described herein.

In the drawings, thicknesses are enlarged for the purpose of clearly illustrating layers and areas. In addition, like elements are denoted by like reference numerals in the whole specification.

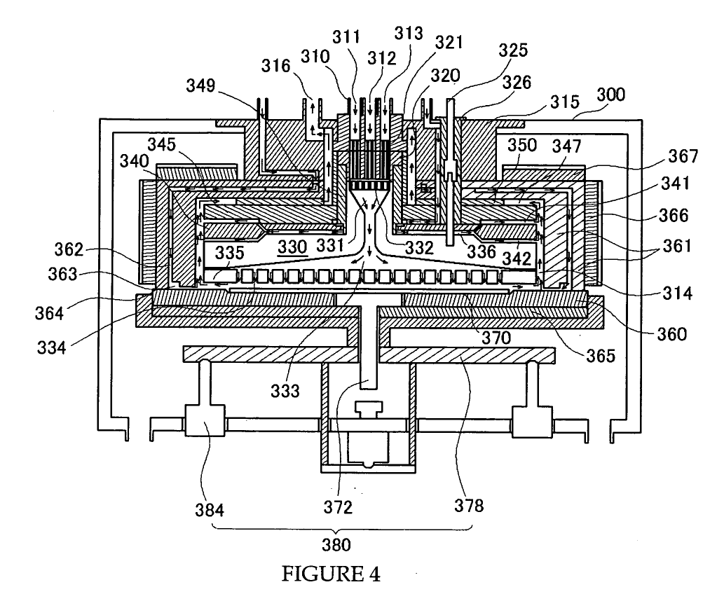

An ALD apparatus according to an embodiment of the present invention will be described in detail with reference to FIG. 4. FIG. 4 is a schematic cross sectional view showing an ALD apparatus according to an embodiment of the present invention.

Referring to FIG. 4, the ALD apparatus according to the embodiment of the present invention includes an outer apparatus wall 300, a gas manifold 315, a gas inflow tube 310, an electrically conductive micro-feeding tube sub-assembly 321, an insulating micro-feeding tube sub-assembly 320, a helical flow inducing plate 332, a reaction chamber wall 361, heaters 366 and 367, a powered gas dispersion structure in the form of a showerhead assembly 330, 335, a substrate support in the form of a pedestal 360, a pedestal driver 380, a gas flow guiding plate 345, a showerhead insulating plate 340, a showerhead assembly insulating pipe 349, pads 350 and 336, and a RF connection port 325.

Now, these components will be described in detail.

A substrate 370 which is subject to deposition is mounted on the pedestal 360, and a heating plate 365 is disposed under the substrate 370 to increase a temperature of the substrate up to a desired process temperature.

The pedestal driver 380 moves the pedestal 360 up and down. The pedestal driver 380 includes a central supporting pin 372 for supporting the pedestal 360, and a moving plate 378 linked to pneumatic cylinders 384, the other ends of which are fixed at a lower portion of the outer apparatus wall 300 of the ALD apparatus.

Before or after the deposition process, the pedestal 360, which is connected to the pneumatic cylinders 384, is moved down and the reaction chamber wall 361 and the pedestal 360 are detached, so that the reaction chamber opens. While the reaction chamber opens, the central supporting pin 372 may be lifted up or moved down, so that the substrate 370 can be detached from the pedestal 360 or mounted on the pedestal 360. The substrate 370 can be loaded or unloaded while the central supporting pin 372 is lifted up relative to the pedestal 370.

After placing a new substrate for deposition, the central supporting pin 372 is dropped down and the substrate 370 is mounted on the pedestal 360. Then the pedestal 360 is lifted up by the pneumatic cylinders 384 close to the reaction chamber wall 361, so that the reaction chamber is closed and reaction space is defined between the pedestal 360 and the showerhead assembly 330, 335.

In order to maintain a suitable inner temperature of the reaction chamber, the separate heaters 366 and 367 are provided to outer surfaces of the reaction chamber wall 361. In order to prevent the loss of heat, generated by the heaters 366 and 367, to the outer apparatus wall 300, the reaction chamber wall 361 has a minimum head conduction path to the outer wall 300, i.e., it is fixed to the outer apparatus wall 300 through the flanged cylinder-type gas manifold 315. Due to such a structure, even though the inner temperature of the reaction chamber is, for example, about 300° C., the temperature of the outer apparatus wall 300 can be maintained at about 65° C. or below. Additional heaters (not shown) may be attached to the gas manifold 315 or inserted into the gas manifold 315.

The gas inflow tube 310 having a plurality of gas inlets 311, 312, and 313 for supplying a plurality of process gases are positioned in the central portion of the gas manifold 315. The electrically conductive micro-feeding tube sub-assembly 321 having a plurality of fine tubules is disposed under and downstream of the gas inflow tube 310.

The insulating micro-feeding tube sub-assembly 320 has a plurality of fine tubules which have the same geometries as those of the electrically conductive micro-feeding tube sub-assembly 321. It is disposed under and downstream of the electrically conductive micro-feeding tube sub-assembly 321. The fine tubules of the electrically conductive micro-feeding tube sub-assembly 321 and the insulating micro-feeding tube sub-assembly 320 are aligned and may be of a size in a range from 0.1 mm to 1.2 mm.

The helical flow inducing plate 332 made of a conductive material is electrically and mechanically to a downstream gas dispersion structure for distributing process gas across the major face of the substrate 370. In the illustrated embodiment, the plate 332 is connected to a volume adjusting horn 330 which constitutes an upper portion of the showerhead assembly 330, 335. The showerhead assembly 330, 335 is constructed with the volume adjusting horn 330 and a gas dispersion perforated grid or faceplate 335. The gas dispersion perforated grid or faceplate 335 is disposed above the substrate 370 in parallel thereto and has perforations 334. The volume adjusting horn 330 has two internal funnels of which the upper end matches with the diameter of the helical flow inducing plate 332, downstream of which the internal passage first narrows and then widens to the lower end, which matches with the diameter of the faceplate 335. The shape of the volume adjusting horn 330 allows the process gas to distribute uniformly, evenly and smoothly over the wafer substrate 370 and, at the same time, minimizes the volume of the inner part of the showerhead assembly 330, 335.

The showerhead assembly 330, 335 is electrically connected to the RF connection port 325, which is constructed with a bar-shaped metal. The RF connection port 325 functions to apply RF power generated by an external RF power generator (not shown) to the showerhead assembly 330, 335. The RF connection port 325 is surrounded with a covering insulating member 326 to avoid short-circuiting with other connection portions.

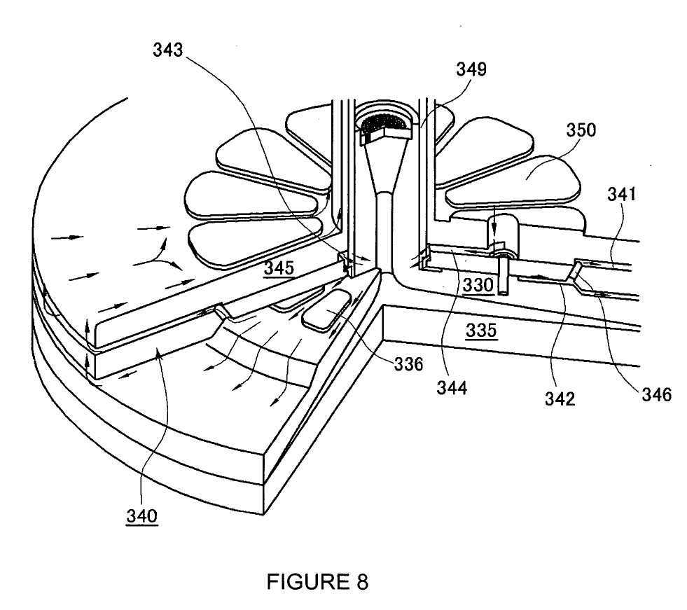

In order to maintain electrical insulation of the showerhead assembly 330, 335, the showerhead insulating plate 340 is disposed on upper face of the volume adjusting horn 330, and the showerhead assembly insulating pipe 349 is disposed at the center of showerhead insulating plate 340 (see also FIG. 8).

The gas flow guiding plate 345 is disposed on the showerhead insulating plate 340 to provide purge and process gas passages 347 and 341. The pads 350 are disposed on the flow guiding plate 345 to define the guiding plate upper gap 347. Similarly a plurality of the pads 336 are symmetrically disposed on the volume adjusting horn 330 to define the insulating plate lower gap 342 between the volume adjusting horn 330 and the showerhead insulating plate 340.

The gas flow guiding plate 345, the showerhead insulating plate 340, and the pads 336, 350 will be described later in detail with reference to FIG. 8.

The reaction chamber wall 361 is constructed with double walls of inner and outer walls. The inner wall is separated from the outer wall to form an inner-chamber-wall gas passage 362 between the inner wall and the outer wall and between the inner wall and the pedestal 360. In addition, a groove is formed along the lower edge of the inner wall to form a gas flow buffering channel 363.

Now, flows of process gases of the ALD apparatus according to the embodiment of the present invention will be described.

In FIG. 4, the arrows denote the flows of the process gases. The process gases pass, in sequence, though the gas inflow tube 310, the electrically conductive micro-feeding tube sub-assembly 321, the insulating micro-feeding tube sub-assembly 320, and the helical flow inducing plate 332. Process gases are dispersed inside the volume adjusting horn 330, and then pass through the spray holes or perforations 334 of the faceplate 335 to meet the surface of the substrate 370. The process and any byproduct gases pass the edge of the substrate 370. Next, the process gases pass through the gap 314 between the side edge of the volume adjusting horn 330 and the reaction chamber wall 361. The process gases pass through the guiding plate upper gap 347 to the gas manifold 315. Finally, the process gases are vented out through the gas outlet 316 to an external vacuum pump (not shown).

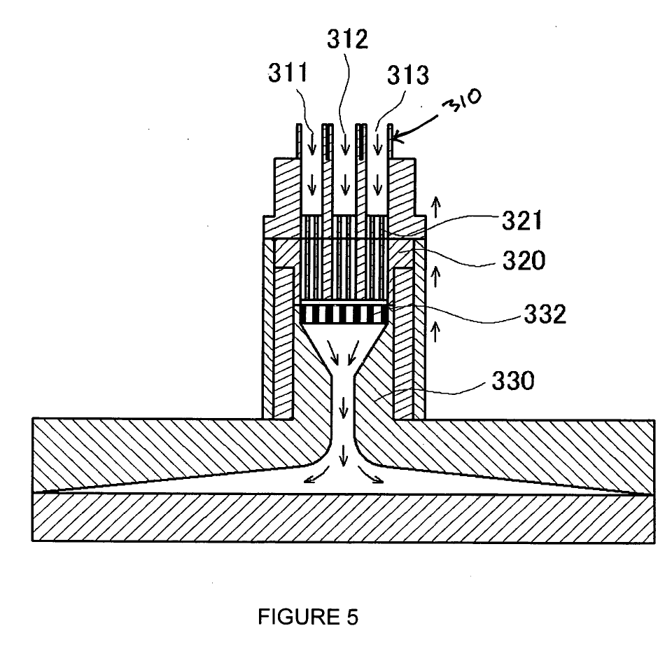

Now, the flow of process gases passing through the gas inlets 311, 312, 313 to be supplied to the substrate 370 will be described in detail with reference to FIGS. 5 to 7.

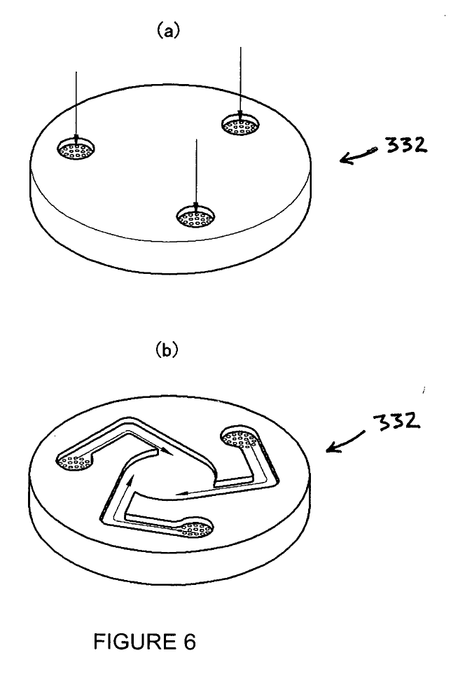

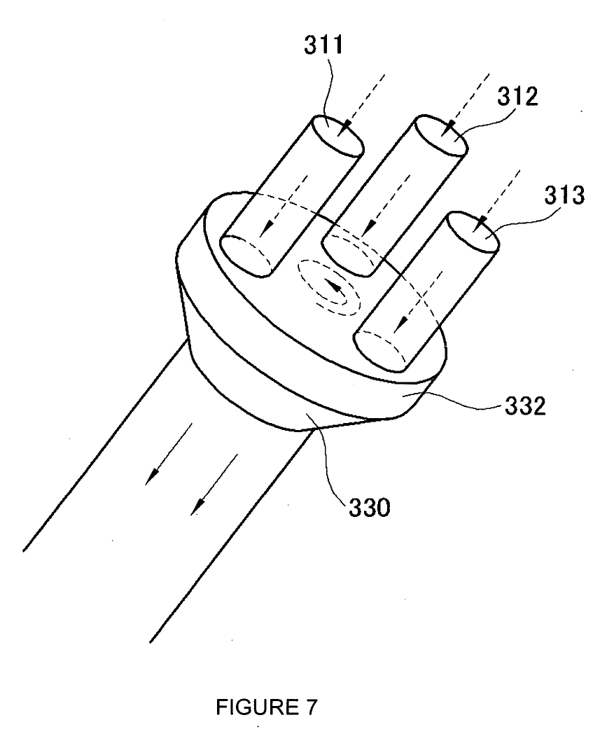

FIG. 5 is an enlarged cross sectional view showing a process gas inflow unit of the ALD apparatus according to the embodiment of the present invention; FIG. 6 is an schematic view showing upper and lower portions of helical flow inducing plate 332 of the process gas inflow unit of the ALD apparatus according to the embodiment of the present invention; and FIG. 7 is a schematic view showing gas flow in the process gas inflow unit, including the inlets 311, 312, 313, the micro-feeding tube assembly 321, 322 and the helical flow inducing plate 332 of the ALD apparatus according to the embodiment of the present invention.

In FIG. 5, the arrows denote the flowing direction of the process gases. The process gases are supplied from process gas sources (not shown) through the gas inlets 311, 312, 313 separated from each other in the gas inflow tube 310 and passes through the electrically conductive micro-feeding tube sub-assembly 321 made of a conductive material and having a plurality of fine tubules. After that, the process gases pass through the insulating micro-feeding tube sub-assembly 320 made of a non-conductive material and having a plurality of fine tubules which have the same number, positions (alignment), and diameters as those of the fine tubules of the electrically conductive micro-feeding tube sub-assembly 321. The process gases passing through the electrically conductive micro-feeding tube sub-assembly 321 and the insulating micro-feeding tube sub-assembly 320 pass through the helical flow inducing plate 332 which is preferably made of a conductive material and connected to the volume adjusting horn 330 electrically and mechanically.

The gas inlets 311, 312, 313 are separated from each other so as to separately supply each of a plurality of process gases. The electrically conductive micro-feeding tube sub-assembly 321 and the insulating micro-feeding tube sub-assembly 320 have a plurality of the fine tubules which are disposed in parallel to each other. Each of the fine tubules of the electrically conductive micro-feeding tube sub-assembly 321 connect and align with one of fine tubules of the insulating micro-feeding tube sub-assembly 320 to form a plurality of single continuous, fine conduits. A plurality of fine holes which have the same number, positions, and diameters as the fine tubules of the electrically conductive micro-feeding tube sub-assembly 321 and insulating micro-feeding tube sub-assembly 320 are formed in an upper portion of the helical flow inducing plate 332 to be aligned to the fine tubules of the micro-feeding tube assembly 321 and 320.

The plurality of the fine tubules in the micro-feeding tube sub-assemblies 321, 320 suppresses generation of plasma within the fine conduits because electrons in such a narrow space cannot be accelerated enough to ionize other molecules or atoms, and thus do not generate plasma.

The insulating micro-feeding tube sub-assembly 320 maintains electrical insulation between the electrically conductive micro-feeding tube sub-assembly 321 and the helical flow inducing plate 332 while allowing the process gases to pass through the fine tubules.

The helical flow inducing plate 332 is electrically connected to the showerhead assembly 330, 335 so as to have an electrical potential equal to that of the volume adjusting horn 330. Accordingly, when a RF power is supplied to the showerhead assembly 330, 335, there is no potential difference between the volume adjusting horn 330 and the helical flow inducing plate 332. Therefore, plasma is not generated in a space between the volume adjusting horn 330 and the helical flow inducing plate 332. It is therefore possible to prevent unnecessary film deposition on inner surfaces of the showerhead assembly 330, 335 and the helical flow inducing plate 332 while performing PEALD. The gap between lower ends of the fine tubules of the insulating micro-feeding tube sub-assembly 320 and the helical flow inducing plate 332 is designed to be narrow (for example, 2 mm or less) enough to prevent or suppress plasma generation.

On the other hand, if the process gases are mixed outside the volume adjusting horn 330 of the ALD apparatus, conductive materials or contaminants may be generated due to chemical reactions of the process gases.

Therefore, it is important to keep the mixing of the process gases only inside the showerhead assembly 330, 335.

In the ALD apparatus according to the illustrated embodiment of the present invention, a plurality of the fine tubules are provided to the electrically conductive micro-feeding tube sub-assembly 321 and the insulating micro-feeding tube sub-assembly 320, and a plurality of the fine holes are provided in the upper portion of the helical flow inducing plate 332. Therefore, the flow rate of the process gases in the fine tubules 321, 320, and the plate 332 having a smaller diameter is higher than the flow rate of the process gases in the gas inlets 311, 312, 313 having a larger diameter. This higher flow rate prevents back-diffusion of the process gases into the gas inlets 311, 312, 313, and thus prevents mixing of those gases outside the showerhead assembly 330, 335. Also there is no mixing of reactive gases inside the fine conduits because the fine tubules are separated for each process gas flow.

In the ALD apparatus according to the embodiment of the present invention, the helical flow inducing plate 332 has a function of effectively mixing the process gases passing through the separate fine conduits by inducing helical flows. Note that, in operation, only one reactant is typically flowed at a time, but the others of the inlets 311, 312, 313 typically include a flowing inert gas while a reactant flows through one of the inlets 311, 312, 313. Thus, the inert and reactant flows mix, rather than mutually reactive reactants. The inert gas may also serve as a reactant, but only upon activation by plasma below the gas inflow unit. Now, the helical flow inducing plate will be described in detail with reference to FIG. 6.

In FIG. 6, (a) is a schematic view of the top view of the helical flow inducing plate 332, and (b) is the bottom view of the helical flow inducing plate 332. Grooves are formed in the lower face of the helical flow inducing plate 332, which grooves are skewed clockwisely or counter-clockwisely. The grooves direct gas flows to a central disc-shaped mixing region. Process gases passing through the grooves form helical flow and mix each other well at the mixing region. The grooves shown in (b) of FIG. 6 are turned about 90° within a horizontal plane; however, they may have a shape of a straight line, an arc, or other shapes.

The process gases passing through the electrically conductive micro-feeding tube sub-assembly 321, the insulating micro-feeding tube sub-assembly 320, and the fine holes in the upper portion of the helical flow inducing plate 332 are accelerated at a high flow rate when passing through the narrow helical flow inducing grooves.

In FIG. 7, the arrows denote the flow direction of the process gases. As shown in FIG. 7, the process gases flowing into the gas inlets 311, 312, 313, substantially perpendicular to the substrate surface, pass through the electrically conductive micro-feeding tube sub-assembly 321, the insulating micro-feeding tube sub-assembly 320, and the fine holes in the upper portion of the helical flow inducing plate 332. The flows of process gases are turned roughly parallel to the substrate, rotate clockwise or counterclockwise when passing through the narrow inducing grooves in the lower portion of the helical flow inducing plate 332, and are again provided with a flow component vector substantially perpendicular to the substrate when passing from the central disc-shaped mixing region into the volume adjusting horn. These helical flows mix the gases flowing from the various inlets 311, 312, 313 well inside the volume adjusting horn 330.

The inner portion of the volume adjusting horn 330 has a shape of funnel so as to induce a laminar flow and smooth dispersion of the mixed process gases. The horn shape also minimizes the inner surface area of the volume adjusting horn 330. Laminar flow and minimum surface area facilitate rapid switching of process gases inside the showerhead assembly 330, 335. Rapid gas switching allows more ALD cycles per unit time, and thus higher film growth rate. Together with the helical flow inducing plate 332, the volume adjusting horn 330 produces a more uniformly distributed (across the substrate surface) and well mixed process gas during each of the relatively short ALD pulses.

In addition, according to the illustrated embodiment, the gas dispersion perforated grid or faceplate 335 allows more uniform process gas supply onto the substrate 370 by passing the gases through the spray holes or perforations 334.

Advantageously, the helical flow inducing plate 332 provides swirling action that distributes the process gas or gas mixture symmetrically with respect to the downstream gas dispersion structure and facing substrate, even though the reactive gas may be asymmetrically introduced through one of the gas inlets 311, 312, 313. Additionally, if during one pulse a reactant is introduced through one of the gas inlets 311, 312, 313 and inert gas is introduced through another of the gas inlets 311, 312, 313, the swirling action mixes these process gases to improve uniformity of the exposure of the substrate to the reactant within the mixture. Accordingly, the skilled artisan will readily appreciate that the helical flow inducing plate 332, downstream of the separate gas inlets 311, 312, 313, provides advantages to distribution uniformity regardless of the particular gas dispersion structure between the plate 332 and the face of the substrate 370. For example, the perforated faceplate 335 can be omitted, and the helical flow inducing plate 332 together with the volume adjusting horn 330 ensure good distribution of process gases introduced perpendicularly to the substrate surface.

With reference again to FIG. 4, in the ALD apparatus according to the illustrated embodiment of the present invention, the RF power is supplied to the showerhead assembly 330, 335 through the RF connection port 325, and the plasma is generated between the electrically grounded pedestal 360 and the faceplate 335, so that the thin film is deposited on the substrate 370.

A film may be deposited if the process gases flow between the showerhead insulating plate 340 and the showerhead assembly 330, 335 to which a RF voltage is applied. Also a film may deposited on the lower portion of the inner wall 361 of the reaction chamber adjacent to on the substrate 370 and the faceplate 335 to which the process gases are supplied. In the ALD apparatus according to the embodiment of the present invention, an inert gas purge is used to prevent such undesirable film deposition.

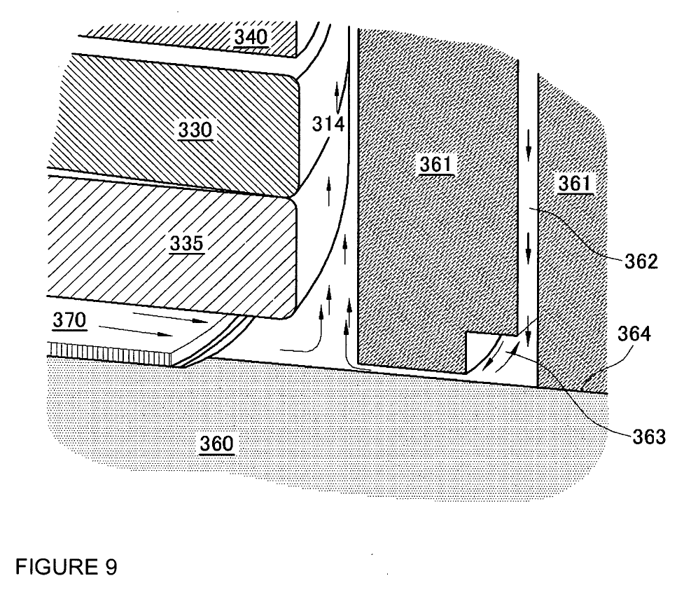

Now, the inert gas flow in the ALD apparatus according to a preferred embodiment of the present invention will be described in detail with reference to FIGS. 8 and 9. FIG. 8 is a schematic perspective view showing the inert gas flow in the ALD apparatus according to the preferred embodiment of the present invention; and FIG. 9 is a schematic view showing the inert gas flow for preventing unnecessary deposition and particle generation in the ALD apparatus according to the embodiment of the present invention. In FIGS. 8 and 9, arrows denote the inert gas flow.

Firstly, returning to FIG. 4, the inert gas is supplied through a gap between the RF connection port 325 and the gas flow guiding plate 345, shown in FIG. 4 to the left of the RF connection port 325. The inert gas may be such as argon (Ar), helium (He) or nitrogen (N₂).

Referring to FIG. 8, the supplied inert gas flows into a circular channel 343 through a gas passage 344 of the RF connection port. Next, the inert gas approaching to the circular channel 343 is uniformed dispersed in the radial direction from the circular channel 343 to flow through the insulating plate lower gap 342 between the volume adjusting horn 330 and the showerhead insulating plate 340. In addition, the inert gas is divided into passages 346 which are formed through the showerhead insulating plate 340 to flow through the insulating plate upper gap 341 between the showerhead insulating plate 340 and the gas flow guiding plate 345. The inert gas passing over the upper and lower surfaces of the showerhead insulating plate 340 is combined with the process and byproduct gases exhausted from the substrate surface. The combined purge gas and process gases passes through the gap between volume adjusting horn 330 and the reaction chamber wall 361, pass through the guiding plate upper gap 347, and then are vented to the gas outlet 316.

An inert gas continuously flows through the gas passages 341 and 342 disposed on the upper and lower surfaces of the showerhead insulating plate 340 to prevent the process gases from forming a thin film on the showerhead insulating plate 340.

As described above, the insulating plate lower gap 342 is defined by the heights of the pads 336, which are symmetrically distributed. The symmetrically disposed pads 336 may be attached to or machined from the upper surface of the volume adjusting horn 330, as illustrated. All the upper surfaces of pads are at the same height so as to closely contact the lower surface of the showerhead insulating plate 340. Alternatively, the pads 336 may be attached to or machined from the underside of the showerhead insulating plate 340. Therefore, assembly variation of the ALD apparatus does not occur, and the insulating plate lower gap 342 is uniformly maintained.

Similarly, a plurality of pads 350 are symmetrically distributed over the gas flow guiding plate 345 so as to define the guiding plate upper gap 347. The pads 350 are precisely attached to or directly machined from the upper portion of the guiding plate 345. Alternatively, the pads may be attached to or machined from the underside of the reaction chamber wall 361 (see FIG. 4). Therefore, without influence of the assembly variation, the guiding plate upper gap 347 (see FIG. 4) is uniformly maintained.

In addition the pads 336 and 350, defining the purge gas passage gaps, conduct heat effectively from the heaters 366 and 367 to the showerhead assembly 330, 335.

Referring to FIGS. 4 and 9, in the double layers of the reaction chamber wall 361, the inner wall is slightly separated from the outer wall. The inert gas can flow through the inner-chamber-wall gas passage 362 formed between the inner wall and the outer wall and between the inner wall and the pedestal 360. In addition, the groove is formed along the lower edge of the inner wall to define the gas flow buffering channel 363 at the contact area 364 between the pedestal 360 and the outer wall of the chamber wall 361. The buffering channel 363 is allowed to have a gas pressure higher than the process pressure of the reaction chamber, so that the inert gas can uniformly flow into the reaction chamber.

Inert gas continuously flows into the gas passage 362 and the buffering channel 363 during the deposition process in order to prevent a thin film from being formed at the contact area 364, where substantial mechanical contact is formed. Films deposited at the contact area may peel off during repetitive contact and detachment from opening and closing the chamber, which may generate contaminant particles in the inner portion of the reaction chamber.

In an ALD apparatus according to the preferred embodiment, when a conductive thin film is deposited by using any of a PEALD process, an ALD process, a combination thereof, and a series thereof, plasma can be stably generated in an inner portion of a reaction chamber without occurrence of electrical short-circuit, so that it is possible to deposit a thin film having an excellent step coverage with precise thickness control.

In an ALD apparatus according to the preferred embodiment, a plurality of process gases for depositing a thin film by using the PEALD or thermal ALD process are separately supplied to the reaction chamber, so that it is possible to prevent a thin film from being deposited outside the reaction space and supply suitably mixed process gases in the reaction chamber.

According to the disclosure herein, it is possible to provide an ALD apparatus using PEALD and thermal ALD processes capable of reducing occurrence of contaminant particles caused by an unnecessary deposition in an inner portion of a reaction chamber and preventing a thin film from being deposited on a rear surface of a substrate.

Although the exemplary embodiments and the modified examples of the present invention have been described, the present invention is not limited to the embodiments and examples, but may be modified in various forms without departing from the scope of the appended claims, the detailed description, and the accompanying drawings of the present invention. Therefore, it is natural that such modifications belong to the scope of the present invention.

What is claimed is:

1. An ALD apparatus for depositing a thin film on a substrate, comprising:
a substrate support;
a reaction chamber wall formed above the substrate support and defining a reaction chamber;
a gas inflow tube connected to a source of process gas and communicating with the reaction chamber;
a showerhead assembly which defines a reaction space together with the substrate support, the assembly including a plurality of holes connected to the gas inflow tube to supply the gas to the reaction space;
a showerhead insulating plate made of an insulating material and disposed on the showerhead assembly;
a gas flow guiding plate disposed between the showerhead insulating plate and the reaction chamber wall;
a gas outlet for venting gas from the reaction chamber; and
a RF connection port connected the showerhead assembly to supply RF power,
wherein gas passages are formed between the showerhead assembly and the showerhead insulating plate, between the showerhead insulating plate and the gas flow guiding plate, and between the gas flow guiding plate and the reaction chamber wall.

2. The ALD apparatus of claim 1, further comprising a plurality of pads symmetrically formed between the showerhead assembly and the showerhead insulating plate, wherein a width of the gas passage between the showerhead assembly and the showerhead insulating plate is defined by heights of the pads.

3. The ALD apparatus of claim 2, wherein the pads are machined directly on the showerhead insulating plate or the showerhead assembly.

4. The ALD apparatus of claim 1, further comprising a plurality of pads symmetrically formed between the gas flow guiding plate and the reaction chamber wall, wherein a width of the gas passage between the gas flow guiding plate and the reaction chamber wall is defined by heights of the pads.

5. The ALD apparatus of claim 4, wherein the pads are machined directly on the gas flow guiding plate or the reaction chamber wall.

6. The ALD apparatus of claim 1, further comprising a gas manifold having gas inlets and outlets.

7. The ALD apparatus of claim 1, wherein the RF connection port passes through the reaction chamber wall and is connected to the showerhead assembly and electrically insulated from the reaction chamber wall.

8. The ALD apparatus of claim 1, further comprising a heating plate disposed under the substrate support to heat the substrate.

9. The ALD apparatus of claim 1, further comprising a heater provided on the reaction chamber wall.

10. The ALD apparatus of claim 1, wherein the substrate support comprises a pedestal configured to lift up to contact the reaction chamber wall to define the reaction chamber, and configured to move down to be separated from the reaction chamber wall, so that the substrate can be mounted or detached.

11. An ALD apparatus for depositing a thin film on a substrate, comprising:
a substrate support;
a reaction chamber wall formed above the substrate support and defining a reaction chamber;
a gas inflow tube having a plurality of separate gas inlets through which a plurality of reaction gases communicate with the reaction chamber;
a gas dispersion structure which defines a reaction space together with the substrate support and is connected to the gas inflow tube to supply the gas to the reaction space;
a micro-feeding tube assembly disposed between the gas inflow tube and the showerhead assembly and having a plurality of fine tubules; and
a helical flow inducing plate disposed between the micro-feeding tube assembly and the gas dispersion structure.

12. The ALD apparatus of claim 11, wherein the micro-feeding tube assembly comprises an electrically conductive micro-feeding tube sub-assembly connected to the gas inflow tube; and an insulating micro-feeding tube sub-assembly connected to the helical flow inducing plate, each of the sub-assemblies having the fine tubules.

13. The ALD apparatus of claim 12, wherein inner diameters of the fine tubules of the electrically conductive micro-feeding tube sub-assembly and the insulating micro-feeding tube sub-assembly are in a range from 0.1 mm to 1.2 mm.

14. The ALD apparatus of claim 12, wherein each of the fine tubules of the electrically conductive micro-feeding tube sub-assembly is aligned with one of the fine tubules of the insulating micro-feeding tube sub-assembly to form a plurality of single conduits.

15. The ALD apparatus of claim 12, wherein the helical flow inducing plate is electrically and mechanically connected to the gas dispersion structure to have an electrical potential equal to that of the gas dispersion structure.

16. The ALD apparatus of claim 12,
wherein a plurality of fine holes formed in an upper portion of the helical flow inducing plate are connected to a plurality of the fine tubules of the insulating micro-feeding tube sub-assembly, and
wherein a plurality of inducing grooves are formed in a lower portion of the helical flow inducing plate for inducing a direction of the gas inflowing through the fine holes and a mixing region formed at the center of the grooves.

17. The ALD apparatus of claim 16,
wherein the inducing grooves have a shape which is curved clockwise,
wherein the mixing region is disc-shaped, and
wherein the inducing grooves are connected to the mixing region so as to contact a circumference of the mixing region.

18. The ALD apparatus of claim 16,
wherein the inducing grooves have a shape which is curved counterclockwise,
wherein the mixing region is disc-shaped, and
wherein the inducing grooves are connected to the mixing region so as to contact a circumference of the mixing region.

19. The ALD apparatus of claim 12, further comprising:
an insulating plate made of an insulating material and disposed on the gas dispersion structure;
a gas flow guiding plate disposed between the insulating plate and the reaction chamber wall;
a gas outlet for venting gas from the reaction chamber; and
a RF connection port connected to the gas dispersion structure to supply RF power,
wherein gas passages are formed between the gas dispersion structure and the insulating plate, between the insulating plate and the gas flow guiding plate, and between the gas flow guiding plate and the reaction chamber wall.

20. The ALD apparatus of claim 19, further comprising a plurality of pads symmetrically formed between the gas dispersion structure and the insulating plate, wherein a width of the gas passage between the gas dispersion structure and the insulating plate is defined by heights of the pads.

21. The ALD apparatus of claim 20, wherein the pads are machined directly on the insulating plate or the gas dispersion structure.

22. The ALD apparatus of claim 19, further comprising a plurality of pads symmetrically formed between the gas flow guiding plate and the reaction chamber wall, wherein a width of the gas passage between the gas flow guiding plate and the reaction chamber wall is defined by heights of the pads.

23. The ALD apparatus of claim 22, wherein the pads are machined directly on the gas flow guiding plate or the reaction chamber wall.

24. The ALD apparatus of claim 19, further comprising a gas manifold having gas inlets and outlets.

25. The ALD apparatus of claim 19, wherein the RF connection port passes through the reaction chamber wall and is connected to the gas dispersion structure and electrically insulated from the reaction chamber wall.

26. The ALD apparatus of claim 19, wherein inner diameters of the fine tubules of the electrically conductive micro-feeding tube sub-assembly and the insulating micro-feeding tube sub-assembly are in a range from 0.1 mm to 1.2 mm.

27. The ALD apparatus of claim 19, wherein each of the fine tubules of the electrically conductive micro-feeding tube sub-assembly is aligned with one of the fine tubules of the insulating micro-feeding tube sub-assembly to form a plurality of single conduits.

28. The ALD apparatus of claim 11, wherein the gas dispersion structure includes a volume adjusting horn with a funnel shape having an inner diameter increasing from an upper portion communicating with the helical flow inducing plate to a lower portion thereof.

29. The ALD apparatus of claim 11, wherein the gas dispersion structure is a showerhead assembly further comprising a gas dispersion perforated grid disposed at the lower portion downstream of the volume adjusting horn, the gas dispersion perforated grid having a plurality of spray holes.

30. The ALD apparatus of claim 29,
wherein the helical flow inducing plate is fixed at an upper opening of the volume adjusting horn, and
wherein the helical flow inducing plate is electrically and mechanically connected to the showerhead assembly to have an electrical potential equal to that of the showerhead assembly.

31. The ALD apparatus of claim 11, wherein the gas inflow tube and the micro-feeding tube assembly are configured to introduce gases substantially perpendicular to the helical flow inducing plate.

32. The ALD apparatus of claim 31, wherein the helical flow inducing plate comprises a plurality of grooves extending in a plane substantially parallel to the substrate support, the grooves configured to direct gases in a spiral prior to entering the gas dispersion structure in a direction substantially perpendicular to the substrate support.
